(19) United States
(12) Patent Application Publication
(10) Pub. No.: US 2016/0021748 A1
(43) Pub. Date: Jan. 21, 2016

(54) WIRING BOARD STRUCTURE AND METHOD OF MANUFACTURING WIRING BOARD STRUCTURE

(71) Applicant: Fujitsu Limited, Kawasaki-shi (JP)

(72) Inventors: HIRONOBU KAGEYAMA, Kawasaki (JP); Susumu Takahashi, Yokohama (JP); Yoshinori Uzuka, Kawasaki (JP)

(21) Appl. No.: 14/740,642

(22) Filed: Jun. 16, 2015

(30) Foreign Application Priority Data
Jul. 17, 2014 (JP) 2014-147146

(51) Int. Cl. H05K 1/14; H05K 3/30; H05K 1/02; H05K 3/36; H05K 1/18; H05K 1/11

(52) U.S. Cl. CPC H05K 1/144; H05K 1/181; H05K 1/111; H05K 1/023; H05K 3/368; H05K 3/303; H05K 2201/10734

(57) ABSTRACT

A wiring board structure includes: a first wiring board includes a first interconnection and a second interconnection constituting a power supply route; a second wiring board mounted over the first wiring board and includes a third interconnection electrically coupled to the first interconnection; a semiconductor chip mounted over the second wiring board and electrically coupled to the third interconnection; a lid mounted over the second wiring board and electrically coupled to the semiconductor chip; and a coupler electrically couples the lid and the second interconnection to each other.

### CROSS-REFERENCE TO RELATED APPLICATION

This application is based upon and claims the benefit of priority of the prior Japanese Patent Application No. 2014-147146, filed on Jul. 17, 2014, the entire contents of which are incorporated herein by reference.

### FIELD

The embodiments discussed herein are related to a wiring board structure and a method of manufacturing the wiring board structure.

### BACKGROUND

For example, the following techniques are known about a wiring board structure including a wiring board such as a printed circuit board and electronic components mounted to the wiring board.

There is known a hybrid module which includes: a circuit board having a predetermined circuit pattern thereon and provided with a concave part in a bottom surface thereof; a semiconductor element mounted to the circuit board while housed in the concave part; and a thermally-conductive and electrically-conductive lid disposed in the opening of the concave part to cover the semiconductor element.

There is also known a semiconductor device which includes: a wiring board where multiple interconnections are stacked on a substrate; and multiple semiconductor elements disposed on the interconnections of the wiring board. In this semiconductor device, a conductive cover with multiple partitions is provided on one surface of the wiring board where the semiconductor elements are disposed. One or more high-frequency operation semiconductor elements are housed in one of the chambers partitioned by one of the partitions, and another semiconductor element is housed in the remaining chamber.

Power is usually supplied to a semiconductor chip via wiring of a printed circuit board on which the semiconductor chip is mounted. A power supply route (current route) including the wiring of the printed circuit board and the like has a wiring resistance of about several micro-ohms to several milli-ohms, for example. Recently, power consumption and current of a semiconductor chip have been in increasing trends along with enhanced performance and integration of semiconductor chips. Therefore, the influence of voltage drop, power loss, and heat generation due to wiring resistance in the power supply route (current route) becomes non-negligible. In particular, supply voltage for driving semiconductor chips has been in a decreasing trend, and thus, higher supply voltage accuracy (about several tens of mV, for example) is requested. A semiconductor chip might malfunction if the voltage drop due to the wiring resistance in the power supply route (current route) including the wiring of the printed circuit board exceeds the requested supply voltage accuracy for the semiconductor chip.

The followings are reference documents:

[Document 1] Japanese Laid-open Patent Publications No. 2005-303209 and

[Document 2] Japanese Laid-open Patent Publications No. 2005-136272.

### SUMMARY

According to an aspect of the invention, a wiring board structure includes: a first wiring board includes a first interconnection and a second interconnection constituting a power supply route; a second wiring board mounted over the first wiring board and includes a third interconnection electrically coupled to the first interconnection; a semiconductor chip mounted over the second wiring board and electrically coupled to the third interconnection; a lid mounted over the second wiring board and electrically coupled to the semiconductor chip; and a coupler electrically couples the lid and the second interconnection to each other.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a sectional view illustrating a configuration of a wiring board structure according to an embodiment of the disclosed technique;

FIG. 2 is a perspective view illustrating the configuration of the wiring board structure according to the embodiment of the disclosed technique;

FIG. 3 is a sectional view illustrating the configuration of the wiring board structure according to the embodiment of the disclosed technique;

FIGS. 4A to 4D are sectional views illustrating a method of manufacturing the wiring board structure according to the embodiment of the disclosed technique;

FIG. 5 is a top view illustrating a form of joining of a lid and a busbar according to the embodiment of the disclosed technique;

FIG. 6 is a sectional view illustrating a form of joining of the busbar and a printed circuit board according to the embodiment of the disclosed technique;

FIG. 7 is a sectional view illustrating a power supply route of the wiring board structure according to the embodiment of the disclosed technique;

FIG. 8 is a diagram illustrating wiring resistance of respective zones in the power supply route of the wiring board structure according to the embodiment of the disclosed technique;

FIG. 9 is a chart illustrating an example of resistance values of the wiring resistance of the respective zones in the power supply route of the wiring board structure according to the embodiment of the disclosed technique;

FIG. 10 is a sectional view illustrating a configuration and a power supply route of a wiring board structure according to a comparative example;

FIG. 11 is a diagram illustrating wiring resistance of respective zones in the power supply route of the wiring board structure according to the comparative example; and

FIG. 12 is a chart illustrating an example of resistance values of the wiring resistance of the respective zones in the power supply route of the wiring board structure according to the comparative example.

### DESCRIPTION OF EMBODIMENT

Hereinafter, an example of an embodiment of the disclosed technique is described with reference to the drawings. Note that, throughout the drawings, the same or equivalent constituents and parts are given the same reference numerals.

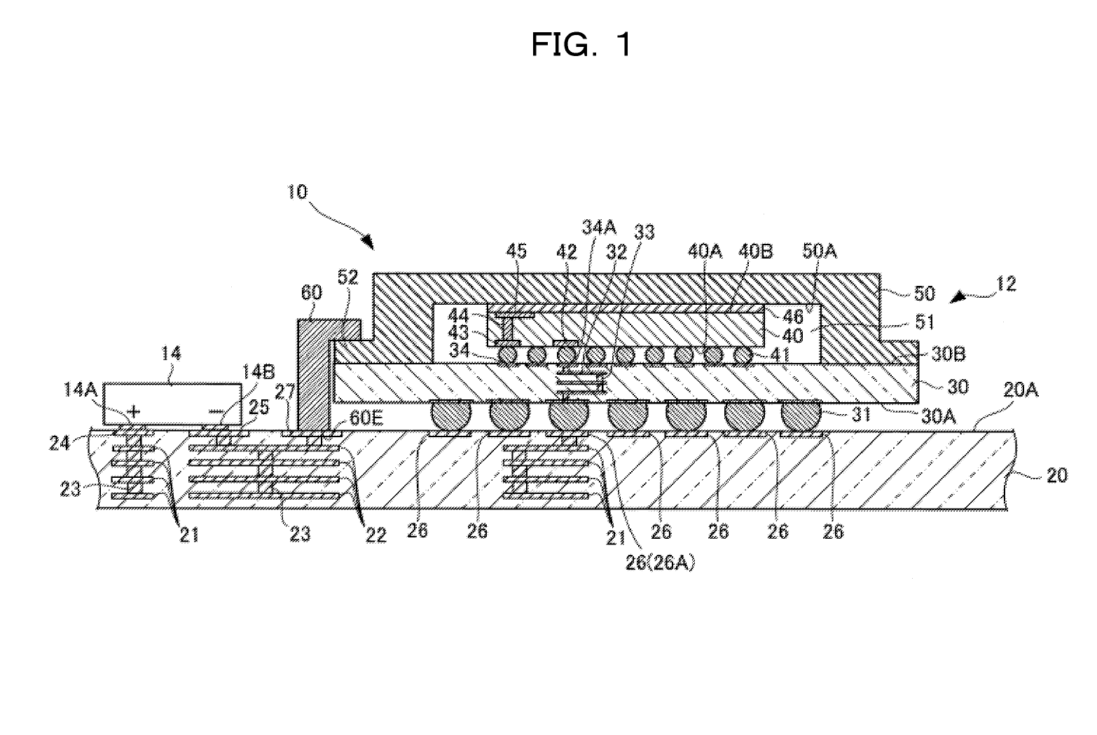

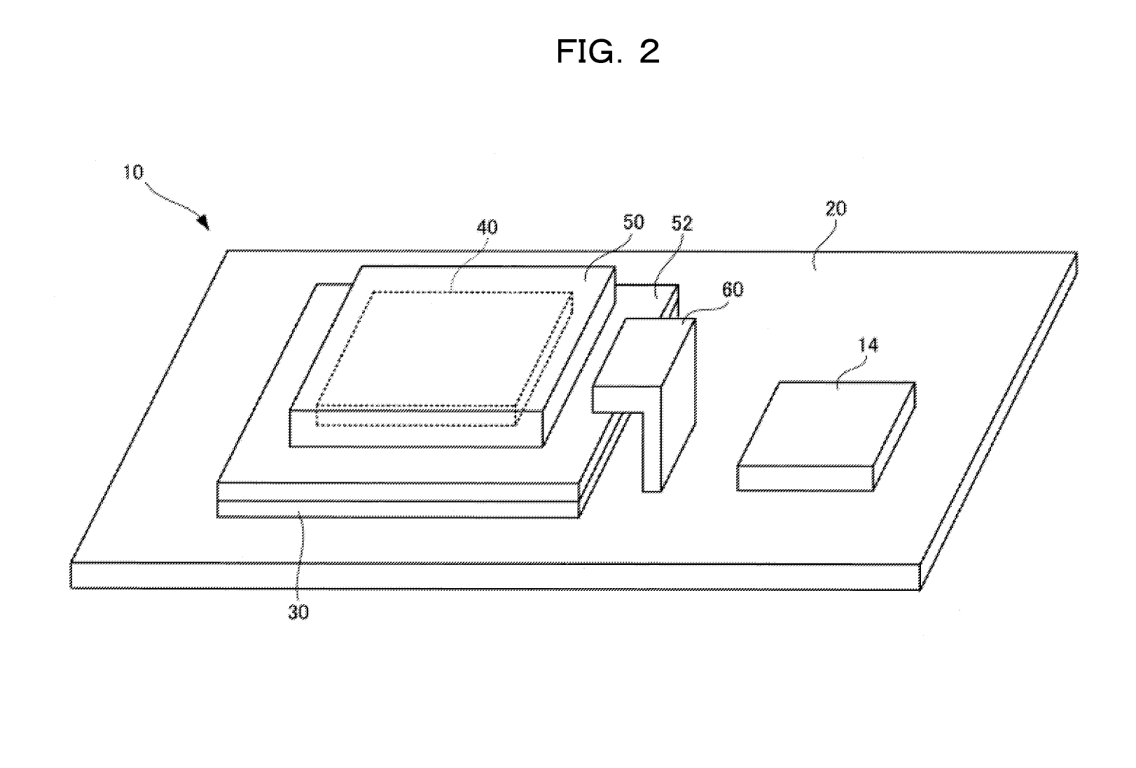

FIG. 1 is a sectional view illustrating a configuration of a wiring board structure 10 according to an embodiment of the disclosed technique. FIG. 2 is a perspective view of the wiring board structure 10. The wiring board structure 10 includes a printed circuit board 20, and a semiconductor package 12 and a power unit 14 that are mounted on the printed circuit board 20.

The printed circuit board 20 is a multilayer wiring board including multiple wiring layers. Although the number of layers of the printed circuit board 20 is 5 in this embodiment, the number of layers is not limited to this. The printed circuit board 20 includes power interconnections 21 and ground interconnections 22 that supply power to a semiconductor chip 40 constituting the semiconductor package 12. The printed circuit board 20 also includes signal wiring (not illustrated) in each wiring layer.

The power interconnections 21 are formed in the wiring layers of the printed circuit board 20 respectively, and the power interconnections 21 of the wiring layers are connected in parallel to each other through via holes 23. Note that, in FIG. 1, power interconnections 21 disposed below the power unit 14 and power interconnections 21 disposed below the semiconductor package 12 are connected to each other inside the printed circuit board 20. Like the power interconnections 21, the ground interconnections 22 are also formed in the wiring layers of the printed circuit board 20, and the ground interconnections 22 of the wiring layers are connected in parallel to each other through via holes 23.

The printed circuit board 20 includes a pad 24 that constitutes a part of the power interconnections 21, and a pad 25 and a pad 27 that constitute a part of the ground interconnections 22. The pads 24, 25, and 27 are exposed on a surface 20A of the printed circuit board 20 on one side thereof on which the semiconductor package 12 and the power unit 14 are mounted.

The power unit 14 is a device that generates power to be supplied to the semiconductor chip 40. The power unit 14 is a DC-DC converter, for example, and configured to output a DC voltage between a positive terminal 14A and a negative terminal 14B. The positive terminal 14A of the power unit 14 is connected to the power interconnections 21 of the printed circuit board 20 via the pad 24, while the negative terminal 14B of the power unit 14 is connected to the ground interconnections 22 of the printed circuit board 20 via the pad 25.

The printed circuit board 20 includes multiple pads 26 corresponding respectively to multiple ball grid array (BGA) connectors 31 provided for the semiconductor package 12. The multiple pads 26 are exposed on the surface 20A of the printed circuit board 20. Among the multiple pads 26, a pad 26A is connected to the power interconnections 21. The other pads 26 are connected to signal wiring (not illustrated), for example.

The semiconductor package 12 includes a package board 30, the semiconductor chip 40, and a lid 50.

The package board 30 is a multilayer wiring board including multiple wiring layers. Although the number of layers of the package board 30 is 5 in this embodiment, the number of layers is not limited to this. The package board 30 includes power interconnections 32 and signal wiring (not illustrated). In this embodiment, the power interconnections 32 are formed in the wiring layers of the package board 30, and the power interconnections 32 of the wiring layers are connected in parallel to each other through via holes 33.

The package board 30 includes the multiple BGA connectors 31 on a surface 30A thereof close to the printed circuit board 20. The BGA connectors 31 are ball-shaped connecting terminals that are arrayed in grids on the surface 30A of the package board 30, and include solder balls, for example. The BGA connectors 31 are respectively connected to the multiple pads 26 (including the pad 26A) of the printed circuit board 20. Thereby, the interconnections of the printed circuit board 20 and the interconnections of the package board 30 are electrically coupled to each other.

The power interconnections 32 of the package board 30 are electrically coupled to the power interconnections 21 of the printed circuit board 20 via the BGA connectors 31 and the pad 26A. In addition, the signal wiring (not illustrated) of the package board 30 is electrically coupled to the signal wiring (not illustrated) of the printed circuit board 20 via the BGA connectors 31 and the pads 26.

The package board 30 includes multiple pads 34 corresponding respectively to multiple bumps 41 provided for the semiconductor chip 40. The multiple pads 34 are exposed on a surface 30B on the side of the package board 30 opposite to the surface 30A. Among the multiple pads 34, a pad 34A is connected to the power interconnections 32. The other pads 34 are connected to signal wiring (not illustrated), for example.

The semiconductor chip 40 is a semiconductor device including an integrated circuit, for example. As an example, the semiconductor chip 40 may be a central processing unit (CPU) that executes arithmetic processing. The semiconductor chip 40 includes the multiple bumps 41 on a surface 40A thereof opposite to the package board 30. The bumps 41 are so-called Controlled Collapse Chip Connection (C4) bumps. The bumps 41 are ball-shaped connecting terminals that are arrayed in grids on the surface 40A of the semiconductor chip 40, and include solder balls. The bumps 41 are respectively connected to the multiple pads 34 (including the pad 34A) of the package board 30.

The semiconductor chip 40 includes, in the surface 40A, a power terminal 42 connected to the pad 34A of the package board 30 via the bumps 41. In other words, the power terminal 42 is electrically coupled to the power interconnections 32 of the package board 30. The integrated circuit built in the semiconductor chip 40 is driven by power supplied through the power terminal 42. The semiconductor chip 40 also includes a ground interconnection 43 in the surface 40A. The ground interconnection 43 is connected to one end part of a through-silicon via (TSV) 44 penetrating the semiconductor chip 40. The semiconductor chip 40 includes a ground terminal 45 in a surface 40B thereof on the side opposite to the surface 40A. The ground terminal 45 is connected to the other end part of the TSV 44. In other words, the ground terminal 45 and the ground interconnection 43 are electrically coupled to each other via the TSV 44. A current flowing into the semiconductor chip 40 from the power terminal 42 passes through the integrated circuit in the semiconductor chip 40 and is output from the ground terminal 45.

A lid 50 is disposed on the surface 30B of the package board 30. The lid 50 has a housing space 51 capable of housing the semiconductor chip 40 and is joined to the surface 30B of the package board 30 while housing the semiconductor chip 40 inside the housing space 51. The lid 50 is made of an electrically-conductive and thermally-conductive material. The lid 50 preferably includes a material having relatively high electrical conductivity and thermal conductivity. For example, copper, iron, aluminum, or stainless steel may be preferably used as a material of the lid 50. As illustrated in FIG. 2, the external shape of the lid 50 may be square or rectangular for example, but is not limited to these shapes.

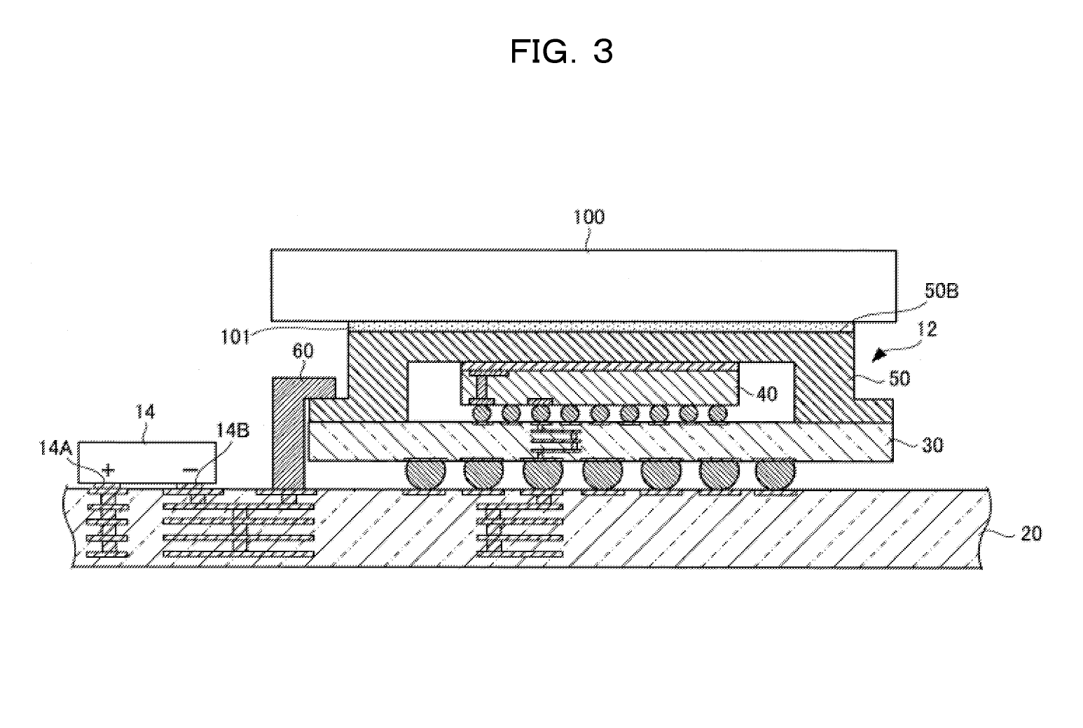

The surface 40B of the semiconductor chip 40 is connected to an inner surface 50A of the lid 50 via a conductive joint member 46. Solder may be used as the joint member 46. The ground terminal 45 exposed on the surface 40B of the semiconductor chip 40 is electrically coupled to the lid 50 via the joint member 46. The lid 50 has functions of protecting the semiconductor chip 40, releasing heat from the semiconductor chip 40 to the outside, and shielding electromagnetic noise from the outside. Further, as will be described later, the lid 50 constitutes a part of a power supply route (current route). Note that, as illustrated in FIG. 3, the heat from the semiconductor chip 40 may be released to the outside efficiently by attaching a heat sink 100 to an outer surface 50B of the lid 50 with an insulating sheet 101 therebetween.

The lid 50 has a flange 52 on an outer peripheral part thereof. A busbar 60 is connected to the flange 52 at a side of the lid 50 close to the power unit 14. In other words, the busbar 60 is placed between the power unit 14 and the semiconductor package 12 (lid 50). The busbar 60 is a rod-shaped member made of a conductor such as copper, iron, aluminum, or stainless steel. The busbar 60 is joined to the lid 50 by a method such as spot welding, screwing, or soldering. The busbar 60 has an “L” shape which bends, at a part joining the lid 50, toward the printed circuit board 20 at an angle of about 90°. An end part 60E of the busbar 60 on the side opposite to an end part thereof on the side of the part joining the lid 50 is connected to the pad 27 of the printed circuit board 20. In other words, the ground terminal 45 of the semiconductor chip 40 is electrically coupled to the ground interconnections 22 of the printed circuit board 20 via the lid 50 and the busbar 60.

Note that the printed circuit board 20 corresponds to a first wiring board of the disclosed technique. The power interconnections 21 of the printed circuit board 20 correspond to a first interconnection of the disclosed technique. The ground interconnections 22 of the printed circuit board 20 correspond to a second interconnection of the disclosed technique. The package board 30 corresponds to a second wiring board of the disclosed technique. The power interconnections 32 of the package board 30 correspond to a third interconnection of the disclosed technique. The semiconductor chip 40 corresponds to a semiconductor chip of the disclosed technique. The power terminal 42 of the semiconductor chip 40 corresponds to a first terminal of the disclosed technique. The ground terminal 45 of the semiconductor chip 40 corresponds to a second terminal of the disclosed technique. The lid 50 corresponds to a lid of the disclosed technique. The busbar 60 corresponds to a coupler of the disclosed technique. The power unit 14 corresponds to a power unit of the disclosed technique.

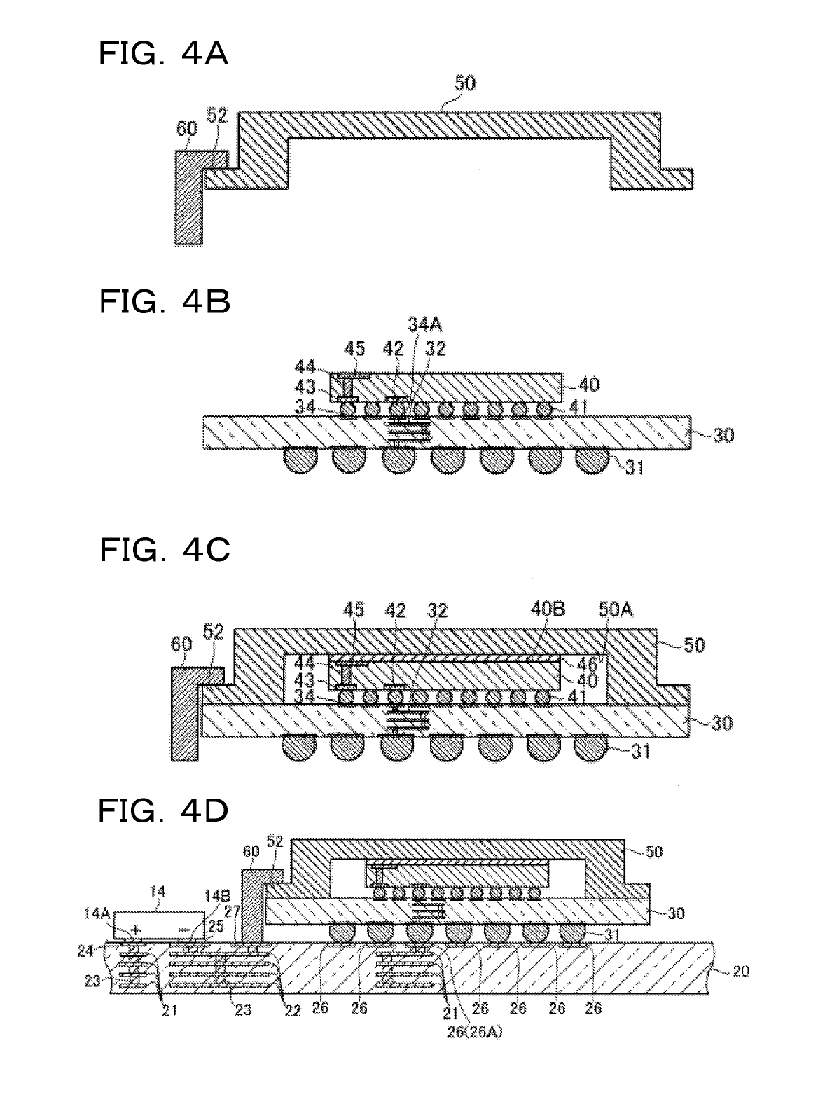

Hereinafter, a method of manufacturing the wiring board structure 10 is described. FIGS. 4A to 4D are sectional views illustrating the method of manufacturing the wiring board structure 10.

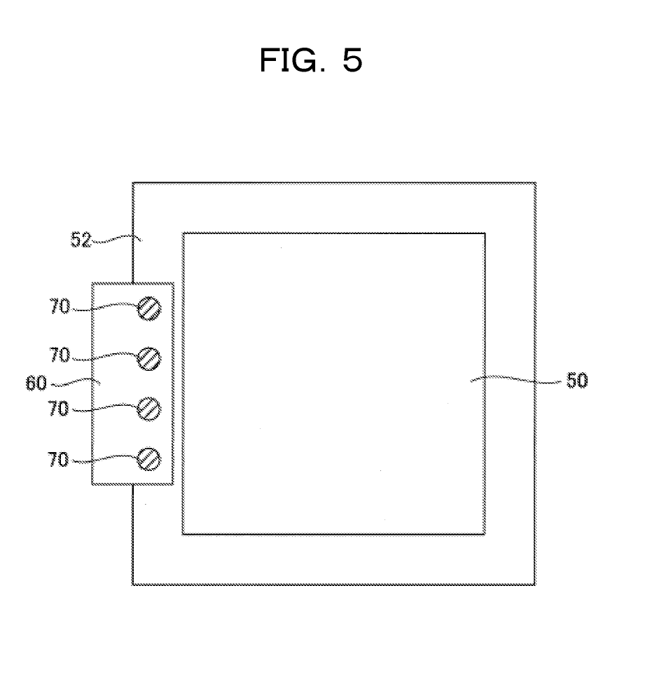

As illustrated in FIG. 4A, the lid 50 and the busbar 60 are joined together. The busbar 60 is joined to the flange 52 of the lid 50 by a method such as screwing, spot welding, or soldering. In spot welding, the busbar 60 is laid over the lid 50 and the busbar 60 and the lid 50 are then energized under pressure with rod-shape electrodes. Here, FIG. 5 is a top view illustrating a case of joining the lid 50 and the busbar 60 by spot welding. As illustrated in FIG. 5, it is preferable to form multiple welding spots 70 in spot welding. Note that spot welding may be employed when the thickness of each of the lid 50 and the busbar 60 is relatively thin, for example, as thin as about 1 mm. Further, when the lid 50 and the busbar 60 are joined together by screwing, it is preferable that multiple spots be screwed as in the case of spot welding.

Subsequently, as illustrated in FIG. 4B, the semiconductor chip 40 and the package board 30 are joined together. Specifically, the semiconductor chip 40 is mounted on the package board 30 such that the bumps 41 of the semiconductor chip 40 come into contact with the respective pads 34 of the package board 30. Then, the solder balls constituting the bumps 41 are melted by a reflow process. Thereby, the semiconductor chip 40 is joined to the package board 30, and the power terminal 42 of the semiconductor chip 40 is electrically coupled to the power interconnections 32 of the package board 30.

Next, as illustrated in FIG. 4C, the lid 50 and the package board 30 are joined together, and the inner surface 50A of the lid 50 is joined to the surface 40B of the semiconductor chip 40 via the joint member 46. Since no electrical connection has to be established between the lid 50 and the package board 30, a resin adhesive may be used to bond the lid 50 and the package board 30 together. On the other hand, since an electrical connection has to be established between the lid 50 and the semiconductor chip 40, solder may be preferably used as the joint member 46. Note that, if soldering is employed to join the lid 50 and the package board 30 and to join the lid 50 and the semiconductor chip 40, these processes may be carried out in a batch operation (batch reflow). The ground terminal 45 of the semiconductor chip 40 is electrically coupled to the lid 50 by joining the surface 40B of the semiconductor chip 40 to the lid 50 via the joint member 46.

Subsequently, as illustrated in FIG. 4D, the package board 30 to which the semiconductor chip 40 and the lid 50 are joined, and the printed circuit board 20 are joined together. Specifically, the package board 30 is mounted on the printed circuit board 20 such that the BGA connectors 31 of the package board 30 come into contact with the respective pads 26 of the printed circuit board 20. Then, the solder balls constituting the BGA connectors 31 are melted by a reflow process to join the package board 30 to the printed circuit board 20. Thereby, the power terminal 42 of the semiconductor chip 40 and the power interconnections 32 of the package board 30 are electrically coupled to the power interconnections 21 of the printed circuit board 20.

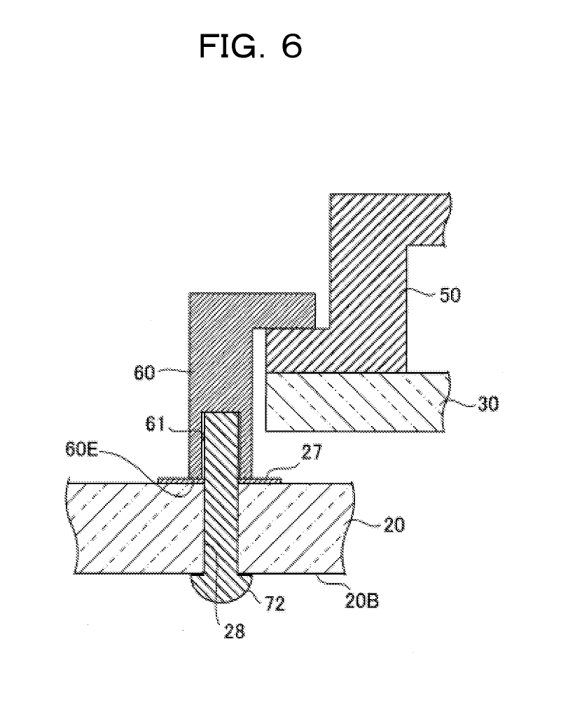

Next, the busbar 60 and the printed circuit board 20 are joined together. The busbar 60 and the printed circuit board 20 may be joined by a method such as screwing or soldering. FIG. 6 is a sectional view illustrating a case of joining the busbar 60 and the printed circuit board 20 by screwing. The end part 60E of the busbar 60 on the side opposite to the end part thereof on the side of the part joining the lid 50 is brought into contact with the pad 27 of the printed circuit board 20. A screw hole 61 is formed in the busbar 60 on the end part 60E side thereof, and a through hole 28 is formed in the printed circuit board 20 at a position where the pad 27 is disposed. Note that the ground interconnections 22 of the printed circuit board 20 are disposed so as to avoid the through hole 28.

A screw 72 is inserted into the through hole 28 from the surface 20B of the printed circuit board 20 and fitted into the screw hole 61 of the busbar 60. Thereby, the busbar 60 and the printed circuit board 20 are joined together. The busbar 60 is electrically coupled to the ground interconnections 22 of the printed circuit board 20. Note that the screw hole 61 and the through hole 28 do not have to be used if the busbar 60 and the printed circuit board 20 are joined by soldering. In addition, if the busbar 60 and the printed circuit board 20 are joined by soldering, the process of joining the package board 30 and the printed circuit board 20 and the process of joining the busbar 60 and the printed circuit board 20 may be carried out in a batch operation (batch reflow).

Note that, although the manufacturing method exemplified above is one in which the busbar 60 and the lid 50 are joined together first, the manufacturing method is not limited to this. For example, joining of the busbar 60 and the lid 50 and joining of the busbar 60 and the printed circuit board 20 may be carried out after the package board 30 to which the semiconductor chip 40 and the lid 50 are joined together and the printed circuit board 20 are joined together.

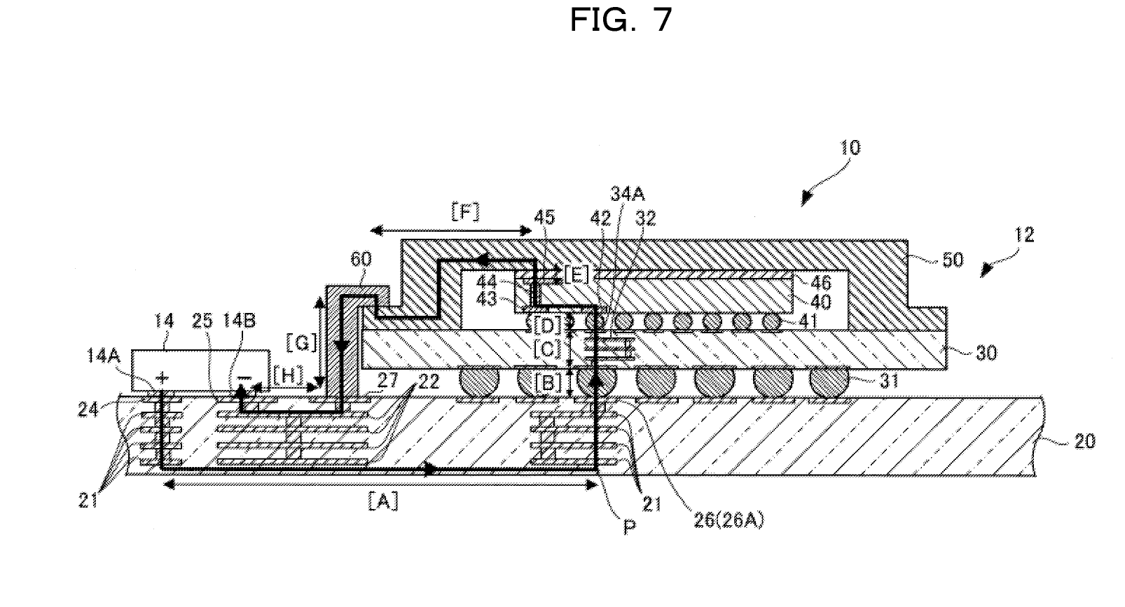

FIG. 7 is a sectional view illustrating a power supply route (current route) P of the wiring board structure 10. Power to be consumed in the semiconductor chip 40 is supplied by the power unit 14. A current output from the positive terminal 14A of the power unit 14 is input to the printed circuit board 20 via the pad 24, passes through the power interconnections 21, and is then output via the pad 26A. A zone in which a current flows through the power interconnections 21 of the printed circuit board 20 is defined as Zone A.

The current output from the printed circuit board 20 via the pad 26A is input to the package board 30 via the BGA connectors 31. A zone in which a current flows through the BGA connectors 31 is defined as Zone B. The current input to the package board 30 flows through the power interconnections 32 of the package board 30 and is then output via the pad 34A. A zone in which a current flows through the power interconnections 32 of the package board 30 is defined as Zone C.

The current output from the package board 30 via the pad 34A is input to the semiconductor chip 40 via the bumps 41. A zone in which a current flows through the bumps 41 is defined as Zone D. The current input to the semiconductor chip 40 passes through the integrated circuit in the semiconductor chip 40, the ground interconnection 43, and the TSV 44 and is then output from the ground terminal 45.

The current output from the ground terminal 45 of the semiconductor chip 40 is input to the lid 50 via the joint member 46. A zone in which a current flows through the joint member 46 is defined as Zone E. The current in the lid 50 flows toward the busbar 60. A zone in which a current flows through the lid 50 is defined as Zone F.

The current input to the busbar 60 passes via the busbar 60 and is input to the printed circuit board 20 via the pad 27. A zone in which a current flows through the busbar 60 is defined as Zone G. The current input to the printed circuit board 20 passes through the ground interconnections 22 and is output via the pad 25. A zone in which a current flows through the ground interconnections 22 of the printed circuit board 20 is defined as Zone H. The current output from the printed circuit board 20 via the pad 25 is input to the negative terminal 14B of the power unit 14.

As described above, the power supply route (current route) P including Zones A to H is defined in the wiring board structure 10. In this way, in the wiring board structure 10, the lid 50 functions as a part of the power supply route (current route) P in addition to the functions of protecting the semiconductor chip 40, releasing heat from the semiconductor chip 40 to the outside, and shielding electromagnetic noise from the outside.

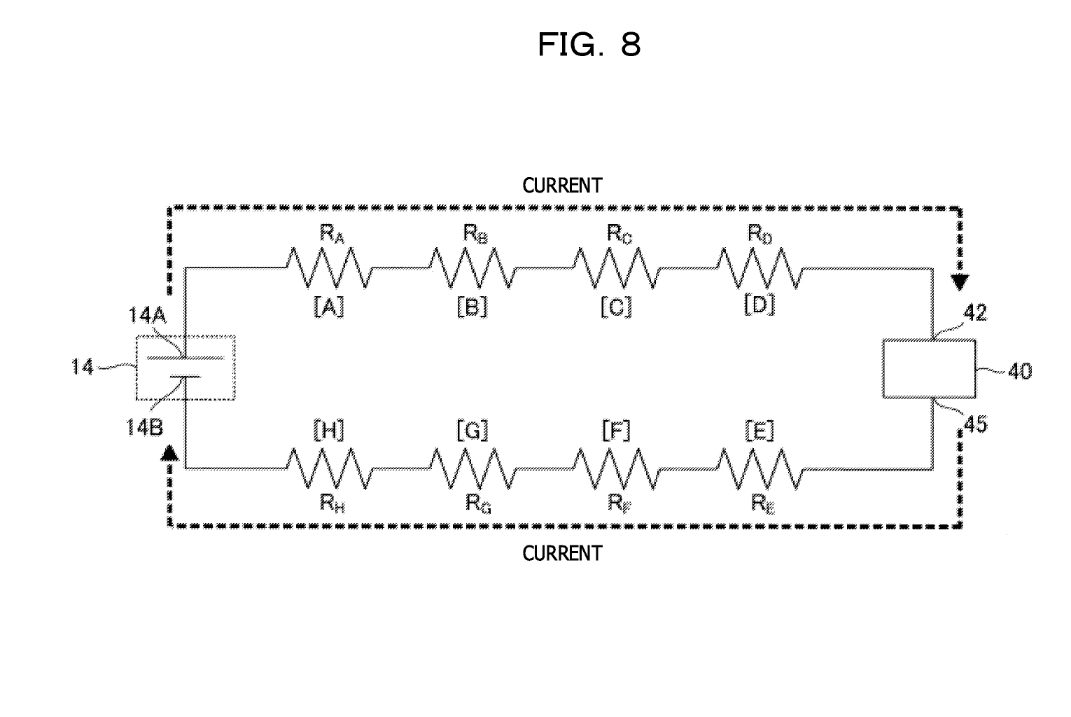

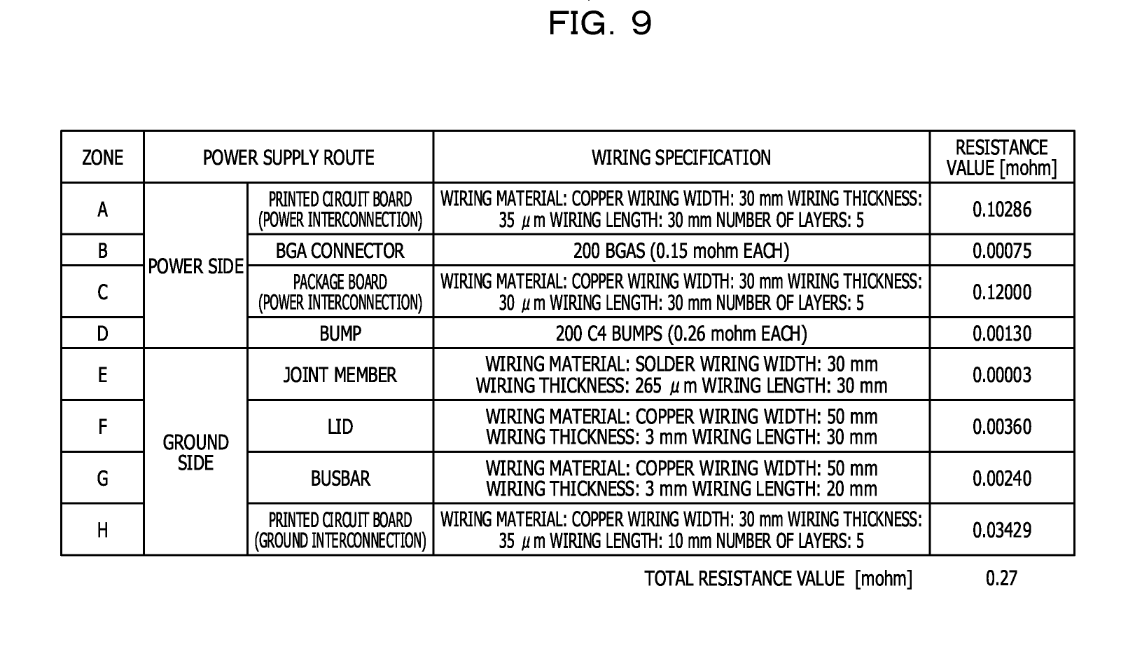

FIG. 8 is a diagram illustrating wiring resistance of respective Zones A to H in the power supply route (current route) P of the wiring board structure 10. The wiring board structure 10 has power-side wiring resistance values R_{A} to R_{D} for respective Zones A to D of the power supply route (current route) P, and has ground-side wiring resistance values R_{E} to R_{H} for respective Zones E to H of the power supply route (current route) P. In FIG. 8, a current flowing through the power supply route (current route) P is denoted by dashed arrows. FIG. 9 is a chart illustrating an example of resistance values of the wiring resistance values R_{A} to R_{H} described above.

A resistance value r of each of the wiring resistance values R_{A} to R_{H} is calculated according to the following formula (1).

r=ρ·L/S (1)

Here, p indicates resistivity of a wiring material. For example, the resistivity of copper is 1.8×10⁻⁸ [ohm·m]. L indicates a wiring length and S indicates the sectional area of wiring.

Zone A is a zone of the power supply route (current route) P including the power interconnections 21 of the printed circuit board 20. An estimated resistance value of the wiring resistance value R_{A} in Zone A is 0.10286 mohm when the wiring material of the power interconnections 21 of the printed circuit board 20 is copper, each power interconnection 21 has a wiring width of 30 mm, a wiring thickness of 35 μm, and a wiring length of 30 mm, and the number of layers of the power interconnections 21 is 5.

Zone B is a zone of the power supply route (current route) P including the BGA connectors 31. An estimated resistance value of the wiring resistance value R_{B} in Zone B is 0.00075 mohm when 200 BGAs each having a resistance value of 0.15 mohm are used.

Zone C is a zone of the power supply route (current route) P including the power interconnections 32 of the package board 30. An estimated resistance value of the wiring resistance value R_{c} in Zone C is 0.12000 mohm when the wiring material of the power interconnections 32 of the package board 30 is copper, each power interconnection 32 has a wiring width of 30 mm, a wiring thickness of 30 μm, and a wiring length of 30 mm, and the number of layers is 5.

Zone D is a zone of the power supply route (current route) P including the bumps 41. An estimated resistance value of the wiring resistance value R_{D} in Zone D is 0.00130 mohm when 200 C4 bumps each having a resistance value of 0.26 mohm are used.

Zone E is a zone of the power supply route (current route) P including the joint member 46. An estimated resistance value of the wiring resistance value R_{E} in Zone E is 0.00003 mohm when the wiring material of the joint member 46 is solder and the joint member 46 has a wiring width of 30 mm, a wiring thickness of 265 μm, and a wiring length of 30 mm.

Zone F is a zone of the power supply route (current route) P including the lid 50. An estimated resistance value of the wiring resistance value R_{F} in Zone F is 0.00360 mohm when the wiring material of the lid 50 is copper and the lid 50 has a wiring width of 50 mm, a wiring thickness of 3 mm, and a wiring length of 30 mm.

Zone G is a zone of the power supply route (current route) P including the busbar 60. An estimated resistance value of the wiring resistance value R_{G} in Zone G is 0.00240 mohm when the wiring material of the busbar 60 is copper and the busbar 60 has a wiring width of 50 mm, a wiring thickness of 3 mm, and a wiring length of 20 mm.

Zone H is a zone of the power supply route (current route) P including the ground interconnections 22 of the printed circuit board 20. An estimated resistance value of the wiring resistance value R_{H} in Zone H is 0.03429 mohm when the wiring material of the ground interconnections 22 is copper, each ground interconnection 22 has a wiring width of 30 mm, a wiring thickness of 35 μm, and a wiring length of 10 mm, and the number of layers is 5.

Accordingly, the total wiring resistance of all the zones of the power supply route (current route) P of the wiring board structure 10 with the above wiring specification is estimated to be 0.27 mohm. Note that the voltage drop is 27 mV and the power loss is 2.7 W when a current of, for example, 100 A flows through the power supply route (current route) P.

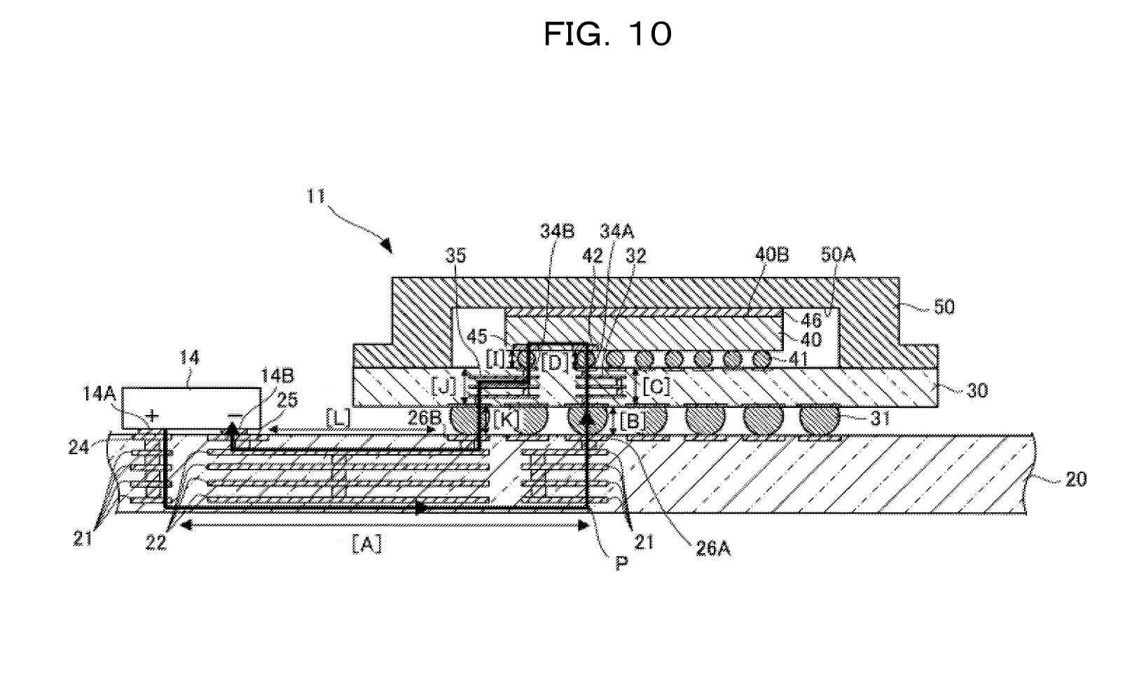

FIG. 10 is a sectional view illustrating a configuration of a wiring board structure 11 according to a comparative example and a power supply route (current route) of the wiring board structure 11. Note that, in FIG. 10, constituents that are the same as or correspond to the constituents of the wiring board structure 10 according to the embodiment of the disclosed technique illustrated in FIG. 1 are given the same reference numerals and are not described here.

The wiring board structure 11 according to the comparative example differs from the wiring board structure 10 according to the embodiment of the disclosed technique in that the wiring board structure 11 does not use the lid 50 as a part of the power supply route (current route). Specifically, in the wiring board structure 11 according to the comparative example, the ground terminal 45 of the semiconductor chip 40 is provided in the same surface as the power terminal 42, and is electrically coupled to ground interconnections 35 of the package board 30 via the bumps 41 and a pad 34B of the package board 30. The lid 50 is joined to the surface 40B of the semiconductor chip 40 via the joint member 46 but is connected to neither the power terminal 42 nor the ground terminal 45, and therefore no current flows through the lid 50. The ground interconnections 35 of the package board 30 are electrically coupled to the ground interconnections 22 of the printed circuit board 20 via the BGA connectors 31 and a pad 26B of the printed circuit board 20.

Zones A to D of the power supply route (current route) in the wiring board structure 11 according to the comparative example are the same as those in the wiring board structure 10 according to the embodiment of the disclosed technique and are therefore not described here.

A current passing through Zones A to D of the power supply route (current route) and then output from the ground terminal 45 of the semiconductor chip 40 passes through the bumps 41 and is input to the package board 30 via the pad 34B. A zone in which a current output from the semiconductor chip 40 flows through the bumps 41 is defined as Zone I.

The current input to the package board 30 via the pad 34B flows through the ground interconnections 35 of the package board 30 and is input to the printed circuit board 20 via the BGA connectors 31 and the pad 26B. A zone in which a current output from the semiconductor chip 40 flows through the ground interconnections 35 of the package board 30 is defined as Zone J, and a zone in which a current output from the semiconductor chip 40 flows through the BGA connectors 31 is defined as Zone K.

The current input to the printed circuit board 20 passes through the ground interconnections 22 and is output via the pad 25. A zone in which a current flows through the ground interconnections 22 of the printed circuit board 20 is defined as Zone L. The current output via the pad 25 is input to the negative terminal 14B of the power unit 14.

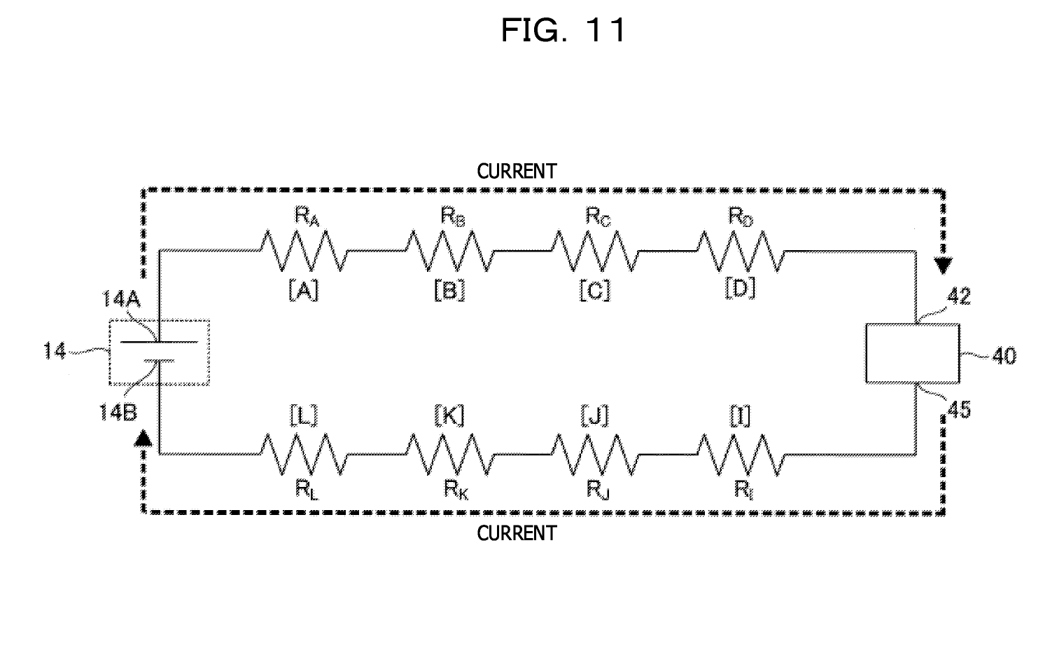

FIG. 11 is a diagram illustrating wiring resistance of respective Zones A to L in the power supply route (current route) P of the wiring board structure 11 according to the comparative example. The wiring board structure 11 according to the comparative example has the power-side wiring resistance values R_{A} to R_{D} for respective Zones A to D of the power supply route (current route) P, and has ground-side wiring resistance values R_{I} to R_{L} for respective Zones I to L of the power supply route (current route) P. In FIG. 11, a current flowing through the power supply route (current route) P is denoted by dashed arrows.

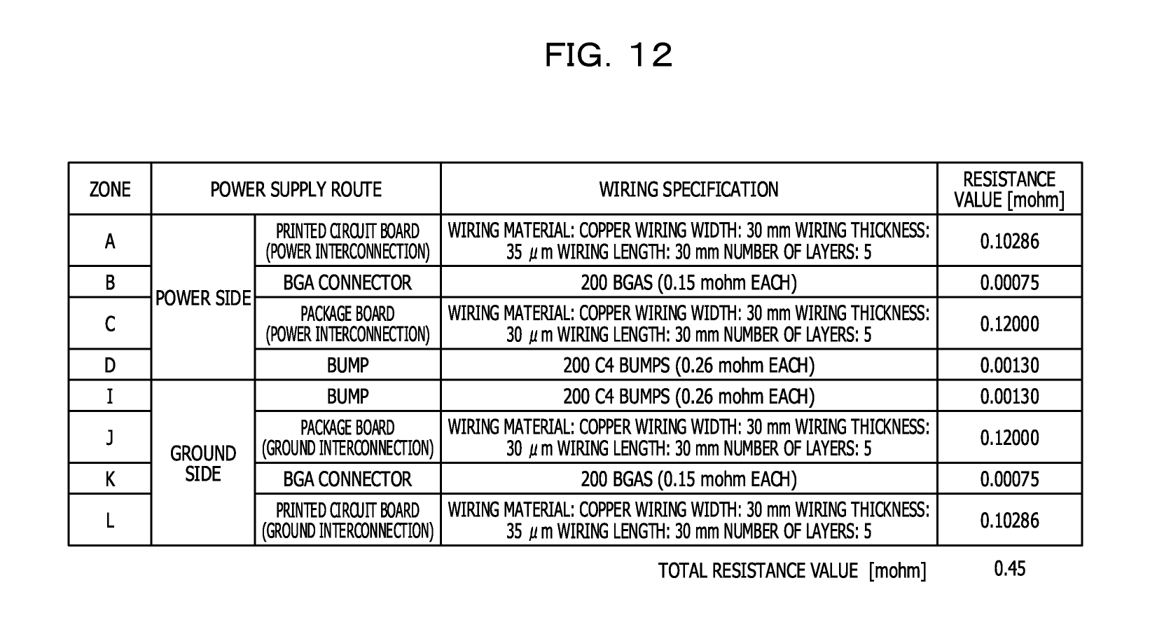

FIG. 12 is a chart illustrating an example of resistance values of the wiring resistance values R_{A} to R_{L} illustrated in FIG. 11. The wiring resistance values R_{A} to R_{D} in Zones A to D are the same as the wiring resistance values R_{A} to R_{D} in Zones A to D of the power supply route (current route) P in the wiring board structure 10 according to the embodiment of the disclosed technique and are therefore not described here.

Zone I is a zone of the power supply route (current route) P including the bumps 41. An estimated resistance value of the wiring resistance value R_{I} in Zone I is 0.00130 mohm when 200 C4 bumps each having a resistance value of 0.26 mohm are used.

Zone J is a zone of the power supply route (current route) P including the ground interconnections 35 of the package board 30. An estimated resistance value of the wiring resistance value R_{J} in Zone J is 0.12000 mohm when the wiring material of the ground interconnections 35 is copper, each ground interconnection 35 has a wiring width of 30 mm, a wiring thickness of 30 μm, and a wiring length of 30 mm, and the number of layers is 5.

Zone K is a zone of the power supply route (current route) P including the BGA connectors 31. An estimated resistance value of the wiring resistance value R_{K} in Zone K is 0.00075 mohm when 200 BGAs each having a resistance value of 0.15 mohm are used.

Zone L is a zone of the power supply route (current route) P including the ground interconnections 22 of the printed circuit board 20. An estimated resistance value of the wiring resistance value R_{L} in Zone L is 0.10286 mohm when the wiring material of the ground interconnections 22 is copper, each ground interconnection 22 has a wiring width of 30 mm, a wiring thickness of 35 μm, and a wiring length of 30 mm, and the number of layers is 5.

Accordingly, the total wiring resistance of all the zones of the power supply route (current route) P of the wiring board structure 11 according to the comparative example with the above wiring specification is estimated to be 0.45 mohm. The voltage drop is 45 mV and the power loss is 4.5 W when a current of, for example, 100 A flows through the power supply route (current route) P.

Hereinafter, the wiring board structure 10 according to the embodiment of the disclosed technique and the wiring board structure 11 according to the comparative example are compared with each other.

The ground-side power supply route (current route) of the wiring board structure 10 according to the embodiment of the disclosed technique includes the joint member 46 (zone E), the lid 50 (zone F), the busbar 60 (zone G), and the ground interconnections 22 of the printed circuit board 20 (zone H). On the other hand, the ground-side power supply route (current route) of the wiring board structure 11 according to the comparative example includes the bumps 41 (zone I), the ground interconnections 35 of the package board 30 (zone J), the BGA connectors 31 (zone K), and the ground interconnections 22 of the printed circuit board 20 (zone L). To put it simply, the ground-side power supply route (current route) of the wiring board structure 10 may be deemed as one in which the lid 50 is used in place of Zone J of the power supply route (current route) including the ground interconnections 35 of the wiring board structure 11 according to the comparative example.

The ground interconnections 35 of the package board 30 are made of a conductor foil. Hence, it is difficult to reduce the resistance value of the wiring resistance of the ground interconnections 35 even if the ground interconnections 35 of the respective wiring layers are connected in parallel to each other with a multilayer wiring technique. On the other hand, because the lid 50 is made of a conductor sufficiently thicker than the ground interconnections 35, the wiring resistance of the lid 50 has a resistance value sufficiently smaller than that of the wiring resistance of the ground interconnections 35. According to the wiring specification exemplified in FIGS. 9 and 12, the total wiring thickness of the five-layered ground interconnections 35 of the package board 30 is 150 μm while the wiring thickness of the lid 50 is 3 mm which is 20 times as thick as the ground interconnections 35. In other words, the resistance value of the lid 50 per unit area (wiring length×wiring width) is one-twentieth the resistance value of the ground interconnections 35 per unit area (wiring length×wiring width).

In addition, in the package board 30, it is not easy to increase the wiring width of wiring including the ground interconnections 35 due to the restrictions of wiring pattern layout. On the other hand, the lid 50 has no such restrictions and therefore increase of its wiring width is relatively easy. According to the wiring specification exemplified in FIGS. 9 and 12, the wiring width of the ground interconnections 35 of the package board 30 is 30 mm while the wiring width (the width of a part through which a current passes) of the lid 50 is 50 mm which is 1.67 times as large as that of the ground interconnections 35.

Accordingly, the wiring board structure 10 according to the embodiment of the disclosed technique may reduce the wiring resistance of the power supply route (current route) by using the lid 50 in place of Zone J of the power supply route (current route) including the ground interconnections 35 of the package board 30 according to the comparative example.

Further, the position where the busbar 60 and the printed circuit board 20 are connected may be located close to the power unit 14 by disposing the busbar 60 at an edge of the lid 50 close to the power unit 14. Hence, it is possible to make the ground interconnections 22 of the printed circuit board 20 of the wiring board structure 10 shorter than the ground interconnections 22 of the wiring board structure 11 according to the comparative example. According to the wiring specification exemplified in FIGS. 9 and 12, the length of the ground interconnections 22 according to the comparative example is 30 mm while the length of the ground interconnections 22 according to the embodiment of the disclosed technique is 10 mm which is one-third the length of the ground interconnections 22 according to the comparative example. In other words, the power supply route (current route) of the wiring board structure 10 according to the embodiment of the disclosed technique may be deemed as one in which the lid 50 is used in place of a part of Zone L of the power supply route (current route) including the ground interconnections 22 of the wiring board structure 11 according to the comparative example.

As in the case of the package board 30, the ground interconnections 22 of the printed circuit board 20 are made of a conductor foil. Hence, it is difficult to reduce the resistance value of the wiring resistance of the ground interconnections 22 even if the ground interconnections 22 of the respective wiring layers are connected in parallel to each other with a multilayer wiring technique. On the other hand, because the lid 50 is made of a conductor sufficiently thicker than the ground interconnections 22, the wiring resistance of the lid 50 has a resistance value sufficiently smaller than that of the wiring resistance of the ground interconnections 22.

According to the wiring specification exemplified in FIGS. 9 and 12, the total wiring thickness of the five-layered ground interconnections 22 according to the comparative example is 175 μm while the wiring thickness of the lid 50 is 3 mm which is 17 times as thick as the ground interconnections 22. In other words, the resistance value of the lid 50 per unit area (wiring length×wiring width) is one-seventeenth the resistance value of the ground interconnections 22 per unit area (wiring length×wiring width).

In addition, in the printed circuit board 20, it is not easy to increase the wiring width of wiring including the ground interconnections 22 as in the case of the package board 30 due to the restrictions of wiring pattern layout. On the other hand, the lid 50 has no such restrictions and therefore increase of its wiring width is relatively easy. According to the wiring specification exemplified in FIGS. 9 and 12, the wiring width of the ground interconnections 22 of the printed circuit board 20 is 30 mm while the wiring width (the width of a part through which a current passes) of the lid 50 is 50 mm which is 1.67 times as large as that of the ground interconnections 22.

Accordingly, the wiring board structure 10 may reduce the wiring resistance of the power supply route (current route) by using the lid 50 in place of a part of Zone L of the power supply route (current route) including the ground interconnections 22 of the wiring board structure 11 according to the comparative example.

As described above, the wiring resistance of the power supply route (current route) P of the wiring board structure 11 according to the comparative example is estimated to be 0.45 mohm, and the wiring resistance of the power supply route (current route) P of the wiring board structure 10 according to the embodiment of the disclosed technique is estimated to be 0.27 mohm.

The voltage drop which would occur when a current of, for example, 100 A flows through the power supply route (current route) P of the wiring board structure 11 according to the comparative example is estimated to be 45 mV. Here, consider a case where the allowable range for the driving voltage applied between the power terminal 42 and the ground terminal 45 of the semiconductor chip 40 is 0.85 V ±5% (±42.5 mV), for example. In this case, if the voltage drops in the power supply route (current route) P is 45 mV, such voltage drop makes the driving voltage applied between the power terminal 42 and the ground terminal 45 of the semiconductor chip 40 fall outside the allowable range. In other words, the semiconductor chip 40 might malfunction if a current of 100 A flows through the power supply route (current route) of the wiring board structure 11.

On the other hand, the voltage drop which would occur when a current of 100 A flows through the power supply route (current route) P of the wiring board structure 10 according to the embodiment of the disclosed technique is estimated to be 27 mV. To put it another way, the driving voltage applied between the power terminal 42 and the ground terminal 45 of the semiconductor chip 40 does not fall outside the allowable range even when a current of 100 A flows through the power supply route (current route) of the wiring board structure 10.

As described so far, according to the wiring board structure 10 of the embodiment of the disclosed technique, it is possible to use the lid 50 in place of Zone J of the power supply route (current route) including the ground interconnections 35 of the package board 30 of the wiring board structure 11 according to the comparative example, and also to use the lid 50 in place of a part of Zone L of the power supply route (current route) including the ground interconnections 22 of the printed circuit board 20 of the wiring board structure 11 according to the comparative example. Thus, the wiring board structure 10 according to the embodiment of the disclosed technique may make the wiring resistance of the power supply route (current route) smaller than the wiring board structure 11 according to the comparative example. Accordingly, the wiring board structure 10 according to the embodiment of the disclosed technique may make the degree of the voltage drop, power loss, and heat generation smaller than the wiring board structure 11 according to the comparative example.

Note that, while the above embodiment exemplifies the case where the lid 50 and the busbar 60 are disposed on the ground side of the power supply route (current route) P, the lid 50 and the busbar 60 may be disposed on the power side thereof. Specifically, in this case, a current output from the positive terminal 14A of the power unit 14 passes through the power interconnections of the printed circuit board 20, the busbar 60, the lid 50, and the joint member 46 and is input to the semiconductor chip 40. The current output from the semiconductor chip 40 passes through the bumps 41, ground interconnections of the package board 30, the BGA connectors 31, and ground interconnections of the printed circuit board 20 and is input to the negative terminal 14B of the power unit 14.

In the case where the semiconductor chip 40 is a multi-power-source device that requests power supply from multiple power units, currents output from multiple power sources are input to the semiconductor chip 40 via multiple power-side power supply routes (current routes) connected to the respective power units, and then meet in a ground-side power supply route (current route). Accordingly, if the semiconductor chip 40 is a multi-power-source device, a larger current flows in the ground-side power supply route (current route) than in each power-side power supply route (current route). Thus, the voltage drop due to the wiring resistance may be suppressed effectively when, out of the power-side and ground-side power supply routes (current routes), the lid 50 is disposed in the ground-side power supply route through which a larger current flows.

In addition, if the lid 50 is disposed on the power side of the power supply route (current route), care has to be taken in order for the lid 50 not to be disposed in contact with other components. Moreover, an electromagnetic noise might be emitted from the lid 50. From these points of view, the lid 50 is preferably disposed on the ground side of the power supply route (current route).

Further, while the above embodiment exemplifies the case where the lid 50 and the busbar 60 are wholly made of a conductor, what is requested is only that at least a part of the lid 50 and the busbar 60 constituting a current route be made of a conductor.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A wiring board structure comprising:
a first wiring board includes a first interconnection and a second interconnection constituting a power supply route;
a second wiring board mounted over the first wiring board and includes a third interconnection electrically coupled to the first interconnection;
a semiconductor chip mounted over the second wiring board and electrically coupled to the third interconnection;
a lid mounted over the second wiring board and electrically coupled to the semiconductor chip; and
a coupler electrically couples the lid and the second interconnection to each other.

2. The wiring board structure according to claim 1, further comprising:
a power unit mounted over the first wiring board and includes a positive terminal and a negative terminal,
wherein the first interconnection and the third interconnection are electrically coupled to the positive terminal, and
the lid, the coupler, and the second interconnection are electrically coupled to the negative terminal.

3. The wiring board structure according to claim 1,
wherein the semiconductor chip includes
a first terminal formed in a surface thereof opposite to the second wiring board, and
a second terminal formed in a surface thereof opposite to the surface opposite to the second wiring board,
the first terminal is electrically coupled to the third interconnection, and
the lid is a conductor, covers the semiconductor chip, and is electrically coupled to the second terminal.

4. The wiring board structure according to claim 3,
wherein the power supply route is a route along which a current output from a positive terminal of a power unit passes through the first interconnection, the third interconnection, the first terminal, the second terminal, the lid, the coupler, and the second interconnection, and reaches a negative terminal of the power unit.

5. The wiring board structure according to claim 4,
wherein the coupler is joined to an edge of the lid close to a mount position of the power unit.

6. The wiring board structure according to claim 1,
wherein the coupler is a rod-shaped member having a first end joined to the lid and a second end joined to the first wiring board.

7. The wiring board structure according to claim 1,
wherein the third interconnection and the first interconnection are electrically coupled to each other via a ball-shaped first coupling terminal.

8. The wiring board structure according to claim 3,
wherein the first terminal and the third interconnection are electrically coupled to each other via a ball-shaped second coupling terminal.

9. A method of manufacturing a wiring board structure comprising:
mounting a second wiring board that includes a third interconnection over a first wiring board that includes a first interconnection and a second interconnection constituting a power supply route, and electrically coupling the third interconnection and the first interconnection to each other;
mounting a semiconductor chip over the second wiring board, and electrically coupling the semiconductor chip and the third interconnection to each other;
joining a coupler made of a conductor to a lid;
mounting the lid with the coupler joined thereto over the second wiring board, and electrically coupling the semiconductor chip and the lid to each other; and
joining the coupler and the first wiring board to each other, and electrically coupling the coupler and the second interconnection to each other.

10. The method of manufacturing a wiring board structure according to claim 9, further comprising:
mounting a power unit over the first wiring board,
wherein the first interconnection and the third interconnection are electrically coupled to a positive terminal of the power unit over the first wiring board, and
the lid, the coupler, and the second interconnection are electrically coupled to a negative terminal of the power unit.

11. The method of manufacturing a wiring board structure according to claim 9,
wherein the semiconductor chip includes a first terminal in a first surface and a second terminal in a second surface,
in the mounting of the semiconductor chip over the second wiring board, the first terminal is electrically coupled to the third interconnection, and
in the mounting of the lid over the second wiring board, the lid is electrically coupled to the second terminal.

12. The method of manufacturing a wiring board structure according to claim 11,
wherein the power supply route is a route along which a current output from a positive terminal of a power unit passes through the first interconnection, the third interconnection, the first terminal, the second terminal, the lid, the coupler, and the second interconnection, and reaches a negative terminal of the power unit, the positive terminal being coupled to the first interconnection and the negative terminal being coupled to the second interconnection.

13. The method of manufacturing a wiring board structure according to claim 12,
wherein the coupler is joined to an edge of the lid close to a mount position of the power unit.

14. The method of manufacturing a wiring board structure according to claim 10,
wherein the coupler is a rod-shaped member having a first end joined to the lid and a second end joined to the first wiring board.

15. The method of manufacturing a wiring board structure according to claim 10,
wherein the third interconnection and the first interconnection are electrically coupled to each other via a ball-shaped coupling terminal.

16. The method of manufacturing a wiring board structure according to claim 12,
wherein the first terminal and the third interconnection are electrically coupled to each other via a ball-shaped coupling terminal.
